(19) United States
(12) Patent Application Publication
(10) Pub. No.: US 2026/0233633 A1
(43) Pub. Date: Aug. 13, 2026

(54) BATTERY MANAGEMENT DEVICE AND METHOD FOR CONTROLLING THE SAME

(71) Applicants: Hyundai Motor Company, Seoul (KR); Kia Corporation, Seoul (KR)

(72) Inventor: Yoon Jun LEE, Hwaseong-Si (KR)

(21) Appl. No.: 19/285,156

(22) Filed: Jul. 30, 2025

(30) Foreign Application Priority Data
Feb. 10, 2025 (KR) 10-2025-0016799

(51) Int. Cl. B60L 58/16; B60L 53/62; B60L 53/66; B60L 58/12

(52) U.S. Cl. CPC B60L 58/16; B60L 53/62; B60L 53/66; B60L 58/12; B60L 2240/545; B60L 2240/547; B60L 2240/549

(57) ABSTRACT

The present disclosure relates to a battery management device and a battery management method that can effectively manage a battery for supplying power to a device. The battery management device for an electrified vehicle, according to an example of the present disclosure, may adjust an entry voltage, which is an entry condition for entering derating control, or a derating rate, applied at the time of entering the derating control, in consideration of internal resistance increased according to the degree of battery degradation. The battery management device may safely control the battery voltage through the adjusted entry voltage or derating rate and provide limited output information to other components.

### CROSS-REFERENCE TO RELATED APPLICATION(S)

This application claims the benefit of priority under 35 U.S.C. 119 to Korean Patent Application No. 10-2025-0016799, filed on Feb. 10, 2025, in the Korean Intellectual Property Office, the entire contents of which is herein incorporated herein for all purpose by this reference.

### TECHNICAL FIELD

The present disclosure relates to a battery management device and a method for controlling the same, wherein a battery voltage can be effectively controlled by considering the degree of a battery's degradation.

### BACKGROUND

High-performance batteries are being increasingly used in electronic devices, ranging from electric vehicles equipped with electric motors to unmanned aerial vehicles and renewable energy storage systems (ESS). These high-performance batteries are typically configured as secondary batteries, which can be repeatedly charged and discharged, making storage capacity and safety crucial.

A battery controller, such as a Battery Management System (BMS), may be employed to control the high-performance batteries and ensure stable operation in the electronic devices using said high-performance batteries. The battery controller/battery management system may perform various roles, such as: monitoring the state of the battery's voltage, current, and/or temperature; calculating a maximum allowable power during charging and/or discharging; maintaining cell balancing; taking protective measures in the event of dangerous situations such as overcurrent and/or short circuit; and recording/monitoring battery charging/discharging and performance data.

Battery management systems may measure a degree of degradation occurring during repeated charging and/or discharging, but may not perform any actions to address any effects of this degradation, such as an increase in internal resistance caused by this degradation.

Therefore, there is a need for an improve battery management system for high-performance batteries.

The matters described in this Background section are only for enhancement of understanding of the background of the disclosure, and should not be taken as acknowledgement that they correspond to prior art already known to those skilled in the art.

### SUMMARY

The following summary presents a simplified summary of certain features. The summary is not an extensive overview and is not intended to identify key or critical elements.

Systems, apparatuses, and methods are described for a battery management device. A battery management device may comprise: a battery; one or more sensors configured to measure one or more of: a voltage of the battery, a temperature of the battery, and a current of the battery; and a battery controller. The battery controller may be configured to: receive, from the one or more sensors, information based on one or more of the voltage, the temperature or the current; determine, based on the information, an increase in an internal resistance associated with degradation of the battery; adjust, based on the increase in the internal resistance, at least one of: an entry voltage for entering derating control to limit an output of the battery, or a derating rate, wherein the derating rate is to limit the output of the battery based on a derating control triggered after the voltage of the battery reaching the entry voltage; and controlling, based on the adjusted at least one of the entry voltage or the derating rate, output of the battery.

Also, or alternatively, a battery management system may comprise: a battery; one or more sensors associated with the battery; one or more devices configured to receive power from the battery; and a battery controller configured to: receive, from the one or more sensors associated with the battery, information indicating a state of health of the battery; determine, based on the information, an increase in an internal resistance of the battery; adjust, based on the increase in the internal resistance, at least one of: an entry voltage for triggering derating control of the battery, or a derating, wherein the derating rate is to limit an output of the battery based on a voltage of the battery reaching the entry voltage; and causing the battery to output, to the one or more devices, power based on the adjusted at least one of the entry voltage or the derating rate.

A battery management method may comprise: receiving, by a battery controller from one or more sensors of a battery, information based on one or more of: a voltage of the battery, a temperature of the battery or a current of the battery; determining, based on the information, an increase in an internal resistance associated with degradation of the battery; adjusting, based on the increase in the internal resistance, at least one of: an entry voltage for entering derating control to limit an output of a battery, or a derating rate, wherein the derating rate is to limit the output of the battery based on a derating control triggered after a voltage reaching the entry voltage; and outputting, by the battery controller, a current output limit value, based on the derating rate, for use based on a voltage of the battery satisfying the entry voltage; and controlling, based on the current output limit value and the adjusted at least one of the entry voltage or the derating rate, power output by the battery.

These and other features and advantages are described in greater detail below.

### BRIEF DESCRIPTION OF THE DRAWINGS

The aspects, features and advantages of the present disclosure will be more apparent from the following detailed description taken in conjunction with the accompanying drawings, in which:

FIG. 1 illustrates an example of the configuration of a battery management device applied to an electrified vehicle according to an example;

FIG. 2 is a flowchart illustrating an example of an operation of managing a limited output by a battery controller according to an example;

FIG. 3 is a flowchart illustrating an example of an entry voltage adjustment operation considering the degree of degradation according to an example;

FIG. 4 illustrates an example of a derating rate adjustment operation considering the degree of degradation according to an example;

FIG. 5 illustrates an example of derating control in a battery in an initial state according to an example;

FIG. 6 illustrates an example of the result of derating control performed when derating conditions are not adjusted in a battery with increased internal resistance;

FIG. 7 illustrates an example of derating control performed when an entry voltage has been adjusted in a battery with increased internal resistance according to an example; and

FIG. 8 illustrates an example of derating control performed when a derating rate has been adjusted in a battery with increased internal resistance according to an example.

### DETAILED DESCRIPTION

Hereinafter, examples set forth will be described in detail with reference to the accompanying drawings. The same or similar elements are given the same and similar reference numerals across figures, so duplicate descriptions of the same or similar elements will be omitted. Furthermore, in describing examples set forth in the specification, a detailed description of known relevant technologies will be omitted when it is determined that the description may make the subject matter of the present disclosure obscure. In addition, it should be appreciated that the accompanying drawings are provided only for the sake of easy understanding of the examples set forth herein, and the technical idea of the present disclosure is not limited to the accompanying drawings and includes all modifications, equivalents, or alternatives falling within the spirit and scope of the present disclosure.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B. “One or more of” is synonymous with “at least one of” herein.

Throughout the present disclosure, references to units (e.g., a control unit) generally refer to items that logically can be grouped together to perform a function or group of related functions. Units may be implemented in software, hardware or a combination of software and hardware. The components, units, modules, and/or functions described above may be implemented and/or performed by one or more processors. For examples, the units may include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The units may also include software control module(s) implemented with a processor or logic circuitry for example. The units may include or otherwise be able to access memory such as, for example, one or more non-transitory computer-readable storage media, such as random-access memory, read-only memory, electrically erasable programmable read-only memory, erasable programmable read-only memory, flash/other memory device(s), data registrar(s), database(s), and/or other suitable hardware. One or more storage type media may include any or all of the tangible memory of computers, processors, or the like, or associated modules thereof, such as various semiconductor memories, tape drives, disk drives and the like, which may provide non-transitory storage at any time for software programming.

Unless otherwise defined, the terms used herein, including technical or scientific terms, may have meanings generally understood by those skilled in the art to which the present disclosure belongs. A singular expression used herein may include the meaning of the plural unless otherwise stated in the context, which also applies to the singular expression described in the claims. The expression “based on” as used herein is intended to describe one or more factors that influence an act or operation of determining or deciding described in a phrase or sentence including that expression, and this expression does not exclude any additional factors that influence the act or operation of determining or deciding.

Depending on the context, the expression “configured to” as used herein may have meanings such as “set to”, “with the ability to”, “modified to”, “made to”, “to be able to”, etc. This expression is not limited to the meaning of “specially designed in hardware to”. For example, a processor configured to perform a specific operation may refer to a generic purpose processor capable of performing the specific operation by executing software, or to a special purpose computer structured through programming to perform the specific operation.

Terms including an ordinal number such as “first” and “second”, etc., may be used to distinguish between various elements, but the elements are not limited by the terms. The above terms are used merely for the purpose of distinguishing one element from other elements.

In the case where an element is referred to as being “connected” or “coupled” to any other elements, it should be understood that not only the element may be directly connected or coupled to the other elements, but also another element may exist therebetween. Contrarily, in the case where an element is referred to as being “directly connected” or “directly coupled” to any other element, it should be understood that no other element exists therebetween.

A singular expression may include a plural expression unless they are definitely different in a context.

As used herein, the expression “include” or “have” are intended to specify the existence of mentioned features, numbers, steps, operations, elements, components, or combinations thereof, and should be construed as not precluding the possible existence or addition of one or more other features, numbers, steps, operations, elements, components, or combinations thereof.

A unit or a control unit included in names such as a motor control unit (MCU) is merely a term widely used for naming a controller configured to control a specific function of a vehicle, but does not mean a generic function unit. The control unit (e.g., controller) may include a communication device communicating with other controllers or a sensor to control one or more functions and/or operations in charge, a memory storing an operation system, a logic command, and input/output information, and/or one or more processors performing determination, calculation, and decision necessary for controlling the function in charge. A controller may include, for example, a processor, a central processing unit (CPU), a microchip, a logic, an application-specific integrated circuit (ASIC), memory, etc. A controller may manipulate and/or control other components in the system (e.g., vehicle). For example, in order to control a function that a control unit is responsible for, the control unit may include a communication device/communication interface configured to communicate with a sensor or another control unit, a memory configured to store an operation system, a logic command, and/or input/output information, and at least one processor configured to perform determination, calculation, decision or the like which are required for the function of controlling.

Examples of the present disclosure control a battery voltage by adjusting an entry voltage (e.g., which is a reference voltage for entering derating control) and/or a derating rate (e.g., slew rate). The derating rate may be a rate at which a limited output is reduced when/if derating control is performed (e.g., in response to reaching the entry voltage) according to a battery's degradation.

For ease of explanation, the following description assumes that a battery management device is applied to a vehicle. However, the present disclosure is not limited thereto and may be applied to various electronic devices, transportation means other than vehicles and/or energy storage systems (ESS). Examples of the present disclosure may include derating control to prevent overvoltage (e.g., during battery charging), and/or derating control to prevent undervoltage (e.g., during battery discharging). Charging of the battery may include charging from an external power source and/or charging via a current generated by a load connected to the battery, such as a motor.

The following will be described with reference to the accompanying drawings to explain the battery management device and associated method for battery management.

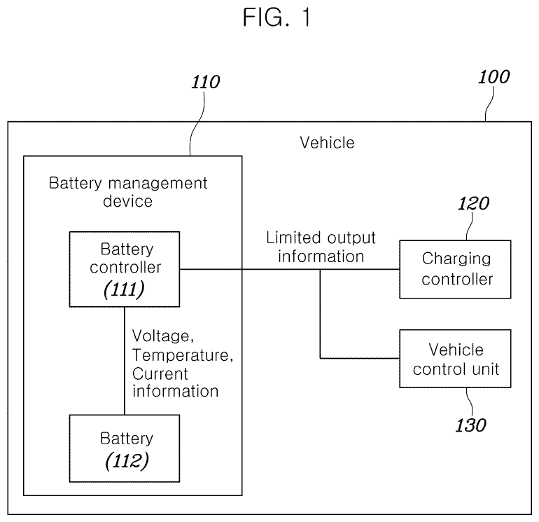

FIG. 1 is a block diagram of a battery management device applied to an electrified vehicle, as an example of a battery management device applicable to examples.

Referring to FIG. 1, an electrified vehicle according to an example may include a battery management device 110, a charging controller 120, and a vehicle control unit 130. Furthermore, the battery management device 110 may include a battery controller 111 and a battery 112. FIG. 1 shows components primarily associated with examples of the present disclosure, and in the actual implementation of the electrified vehicle, may include more or fewer components than shown.

The vehicle 100 may, based on the battery management device 110, receive power from the battery 112 to provide the power to a driving source and electronic devices. The battery controller 111 may serve to control a state of charge and/or discharge of the battery 112, protect the battery 112, and/or provide limited power information to one or more other controllers, such as the charging controller 120 and/or the vehicle control unit 130.

If an external charging device, such as an electric vehicle supply equipment (EVSE), is connected to the vehicle 100 (e.g., via a charging cable), the charging controller 120 may exchange data required for charging with the EVSE (e.g., via wired and/or wireless communication) and thereby control the charging process. For example, the charging controller 120 may control charging current and voltage (e.g., to prevent overcharging) based on the limited output information received from the battery controller 111. The charging controller 111 may be implemented in the form of a vehicle charging management system (VCMS), as a nonlimiting example.

The vehicle control unit (VCU) 130 may function as a higher-level controller that performs one or more integrated control functions of a power electric (PE) system. For example, in an electric vehicle (EV), the vehicle control unit 130 may determine a driver's requested torque based on the degree of accelerator pedal manipulation, and may transmit a corresponding torque command to a motor controller (not shown) and/or transmit a regenerative torque command to the motor controller based on braking demand torque. In relation to an example of the present disclosure, the vehicle control unit 130 may determine the torque command and/or the regenerative torque command within a range where battery input/output power does not exceed the limited output information, based on the limited output information received from the battery controller 111.

The limited output information, output by the battery controller 111, may be referenced/used by the charging controller 120 if/when the vehicle 100 receives power from an external charging device. The limited output information, output by the battery controller 111, may be referenced/used by the vehicle control unit 130 if/when the vehicle 100 is in motion/operation for generating/determining vehicle control commands, and/or in controlling the charging and/or discharging of the battery 112.

Based on the configuration of the battery management device described herein, a method for outputting battery voltage management and limited output information according to an example is described as follows.

The battery controller 111 of the battery management device 110 may acquire information about the voltage, temperature, and/or current of a battery. One or more sensors (e.g., a voltage sensor, a temperature sensor and/or a current sensor) may be configured to measure a voltage, a temperature and/or a current of the battery, and the battery controller 111 may receive the measured voltage, temperature and/or current of the battery 112 and/or information based on the measured voltage, temperature and/or current of the battery 112 (e.g., information indicating one or more of the voltage, temperature and/or current of the battery satisfy one or more criteria associated with potential degradation of the battery). The battery controller 111 may determine a degree of the battery's degradation based on one or more indicators such as state of health (SOH) of the battery 112. For example, the battery controller 111 may determine/calculate the SOH of the battery 112 based on the received voltage, temperature and/or current of the battery (e.g., via a programmed calculation process). For example, in order to operate the battery safely, output limit control (e.g., derating control) may be performed to control the battery voltage so that the voltage is not lower than a lower limit voltage or higher than an upper limit voltage. The following describes the derating control.

Whether to enter derating control may be determined based on whether a voltage of the battery 112 satisfies a voltage condition for the battery 112. The voltage condition may include an upper limit entry voltage and/or a lower limit entry voltage. The upper limit entry voltage may be configured/determined in consideration of (e.g., based on) a voltage margin from a predetermined upper limit voltage for overcharge/overvoltage protection of the battery. The upper limit entry voltage may be applied as the voltage condition based on the voltage of the battery 112 rising (e.g., during charging). For example, the upper limit entry voltage may be applied as the voltage condition based on a measured voltage (e.g., received from the voltage sensor) indicating the voltage is rising and/or another indication that the voltage of the battery 112 is rising. The lower limit entry voltage may be configured/determined in consideration of/based on a predetermined lower limit voltage for overdischarge/undervoltage protection of the battery. For example, the lower limit entry voltage may be higher than the predetermined lower limit voltage by a voltage margin. The lower limit entry voltage may be applied as the voltage condition based on the voltage of the battery 112 dropping (e.g., during discharging). For example, the lower limit entry voltage may be applied as the voltage condition based on a measured voltage (e.g., received from the voltage sensor) indicating the voltage of the battery 112 is dropping and/or another indication that the voltage of the battery 112 is dropping. Thus, the derating control may be activated based on the voltage of the battery 112 rising to satisfy (e.g., reach and/or exceed) the upper limit entry voltage, and/or based on the voltage dropping to satisfy (e.g., reach and/or drop below) the lower limit entry voltage.

The battery controller 111 may, based on determining to enter the derating control, apply a derating rate (e.g., slew rate) to reduce a current limited output over time. The battery controller 111 may output information (“limited output information” herein) about the current limited output (e.g., based on application of the derating rate) in real time (e.g., as/based on being generated) and/or at a predetermined interval (e.g., as batched information). As described herein, the limited output information may be referenced by the charging controller 120 and/or the vehicle control unit 130 depending on the situation, so that the charging and/or discharging speed can be adjusted to prevent the voltage of the battery 112 from reaching the predetermined upper and/or lower limit voltage.

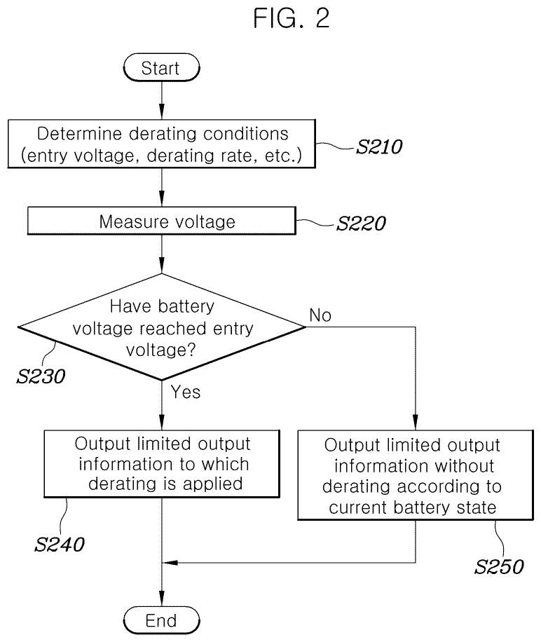

FIG. 2 is a flowchart illustrating an example of an operation of managing a limited output by a battery controller according to an example. For convenience, FIG. 2 is described by way of an example in which the steps are performed by a processor circuit. One, some, or all steps of the example method of FIG. 2, or portions thereof, may be performed by one or more other circuits. One or some, steps of the example method of FIG. 2 may be omitted, performed in other orders, and/or otherwise modified, and/or one or more additional steps may be added.

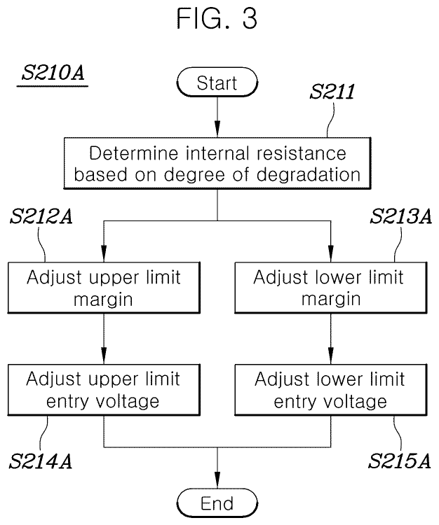

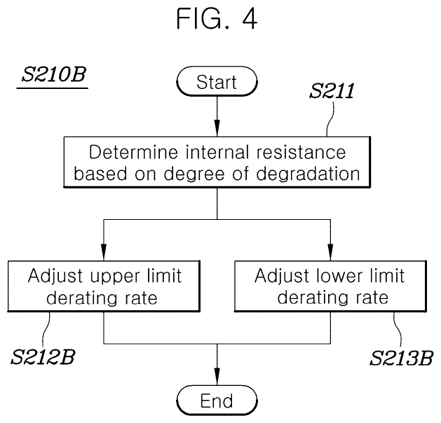

Referring to FIG. 2, the battery controller 111 may determine derating conditions (S210). The derating conditions may include an entry voltage and/or a derating rate to be applied (e.g., if/when entering derating control). The derating conditions may be default conditions (e.g., originally programmed) if the battery 112 is in an initial state (e.g., birth of life (BOL)). One or more of the conditions may be adjusted (e.g., from the default conditions) depending on, for example, indications of degradation of the battery 112 (e.g., changes in internal resistance due to the degradation of the battery 112). Example adjustment methods will be described with reference to FIGS. 3 and 4.

The battery controller 111 may measure/determine the voltage of the battery 112 (S220). The battery controller 111 may receive a measurement of the voltage from a voltage sensor configured to measure the voltage of the battery 112. Also, or alternatively, the battery controller 111 may receive information based on the measured voltage S220 (e.g., from the voltage sensor). The battery controller may compare the measured voltage with one or more entry voltage thresholds (e.g., an upper limit entry voltage and/or lower limit entry voltage, depending on the direction of change, to determine whether to enter derating control (S230). Also, or alternatively, the information based on the measured voltage S220 may indicate results of a comparison with the one or more entry voltage thresholds (e.g., the information may indicate whether the measured voltage satisfies one or more of the entry voltage thresholds) (S230). For example, the battery controller 111 and/or voltage sensor may determine whether the voltage of the battery 112 reaches the upper limit entry voltage based on the voltage of the battery 112 rising, and/or whether the voltage of the battery 112 reaches the lower limit entry voltage based on the voltage of the battery 112 dropping.

If the voltage of the battery 112 satisfies (e.g., has reached and/or is outside of) the entry voltage (Yes in S230), the battery controller 111 may output limited output information, adjusted by applying the derating rate (S240).

If the voltage of the battery 112 does not satisfy (e.g., has not reached and/or is within) the entry voltage (No in S230), the battery controller 111 may output limited output information based on the current state (e.g., charging state and/or temperature, etc.) of the battery (e.g., instead or/without applying the derating rate) (S250).

Determining the derating conditions (S210) in FIG. 2 will be described in more detail with reference to FIGS. 3 and 4. As described herein, the derating conditions may include an entry voltage and/or a derating rate. An entry voltage determination operation S210A will be described with reference to FIG. 3 and a derating rate determination operation S210B will be described with reference to FIG. 4.

FIG. 3 is a flowchart illustrating an example of an entry voltage adjustment operation considering the degree of degradation according to an example. For convenience, FIG. 3 is described by way of an example in which the steps are performed by a processor circuit. One, some, or all steps of the example method of FIG. 3, or portions thereof, may be performed by one or more other circuits. One or some, steps of the example method of FIG. 3 may be omitted, performed in other orders, and/or otherwise modified, and/or one or more additional steps may be added.

Referring to FIG. 3, the battery controller 111 may determine the internal resistance according to/based on the degradation degree of the battery 112 (e.g., the state of health (SOH)) (S211). Various methods for determining the internal resistance according to the SOH are well known to those skilled in the art, and a detailed description of the determination process will be omitted. Based on the internal resistance, the battery controller 111 may adjust an upper limit margin (S212A) and/or a lower limit margin (S213A).

For example, the upper limit margin may be obtained by multiplying a predetermined margin (e.g., based on/of an initial/default (BOL) state) by the percentage increase in internal resistance. That is, if/when the current internal resistance has increased by 10% compared to the initial state, the upper limit margin may be adjusted by a factor of 1.1. As the upper margin increases, the upper limit entry voltage may decrease accordingly. The method for obtaining the lower limit margin may be similar to the method for obtaining the upper limit margin, and thus a redundant description will be omitted.

For example, the battery controller 111 may be configured to adjust the entry voltage per Equation 1 during/based on charging of the battery:

$${V}_{U E} = {V}_{U T} - ( {V}_{U T} - {V}_{U E}^{0} ) \cdot ( \frac{R}{{R}^{0}} ) \cdot {w}_{1} \qquad [ Equation 1 ]$$

wherein V_{U}E is the adjusted entry voltage, V_{UT} is the predetermined battery upper limit voltage,

$${V}_{UE}^{0}$$

is the entry voltage before adjustment, R⁰ is the battery internal resistance before increase, R is the internal resistance increased according to the degree of degradation, w₁ is a first weight.

The battery controller may also, or alternatively, be configured to adjust the entry voltage per Equation 3 during/based on discharging of the battery:

$${V}_{L E} = {V}_{L T} + ( {V}_{L E}^{0} - {V}_{L T} ) \cdot ( \frac{R}{{R}^{0}} ) \cdot {w}_{1} \qquad [ Equation 3 ]$$

wherein V_{LE} is the adjusted entry voltage, V_{LT} is the predetermined battery lower limit voltage,

$${V}_{L E}^{0}$$

is the entry voltage before adjustment, R⁰ is the battery internal resistance before increase, R is the internal resistance increased according to the degree of degradation, and w₂ is a second weight.

The battery controller 111 may determine an upper limit entry voltage (e.g., the upper limit voltage minus the upper limit margin) based on the obtained upper limit margin (S214A) and/or a lower limit entry voltage (i.e., the lower limit voltage plus the lower limit margin) based on the obtained lower limit margin (S215A).

FIG. 4 illustrates an example of a derating rate adjustment operation considering the degree of degradation according to an example. For convenience, FIG. 4 is described by way of an example in which the steps are performed by a processor circuit. One, some, or all steps of the example method of FIG. 4, or portions thereof, may be performed by one or more other circuits. One or some, steps of the example method of FIG. 4 may be omitted, performed in other orders, and/or otherwise modified, and/or one or more additional steps may be added.

Referring to FIG. 4, the battery controller 111 may determine internal resistance based on the degree of battery degradation (e.g., SOH) (S211). The battery controller 111 may adjust an upper limit derating rate based on the determined internal resistance (S212B) and/or a lower limit derating rate based on the determined internal resistance (S213B).

For example, an upper limit derating rate may be obtained by multiplying a predetermined derating rate (e.g., based on/of an initial/default (BOL) state) by the percentage increase in internal resistance. For example, assuming an initial derating rate (slew rate) of 1.0, if the current internal resistance has increased by 10% from the initial state, the upper derating rate may be adjusted to 1.1. The method for obtaining a lower limit derating rate may be similar to the method for obtaining the upper limit derating rate, and thus a redundant description will be omitted.

The entry voltage adjustment described in FIG. 3 and the derating rate adjustment described in FIG. 4 may be performed separately and/or together. In this case, weights may be assigned to the adjustments (e.g., according to the needs/goals of those skilled in the art). The weights may be changed based on a vehicle's conditions. For example, if a condition/goal is to use a high discharge output for as long as possible, the weight of the lower limit entry voltage adjustment may be reduced to delay entry into derating control, but after entering the derating control, the weight of derating rate adjustment may be increased to quickly reduce an output and enable undervoltage protection. For example, if/when a condition/goal is to achieve stable battery protection, the weight of the lower limit entry voltage adjustment may be increased to accelerate entry into derating control, and/or the weight of the derating rate adjustment may be reduced to apply the output limit more gradually.

For example, the battery controller may be configured to adjust the derating rate per Equation 2 during/based on charging of the battery:

$$S {R}_{U} = S {R}_{U}^{0} \cdot ( \frac{R}{{R}^{0}} ) \cdot {w}_{2} \qquad [ Equation 2 ]$$

wherein SR_{U} is the adjusted derating rate,

$$S {R}_{U}^{0}$$

is the derating rate before adjustment, R⁰ is the battery internal resistance before increase, R is the internal resistance increased according to the degree of degradation, and w₂ is a second weight.

For example, the battery controller may be further configured to adjust the derating rate per Equation 4 during/based on discharging of the battery:

$$S {R}_{L} = S {R}_{L}^{0} \cdot ( \frac{R}{{R}^{0}} ) \cdot {w}_{2} \qquad [ Equation 4 ]$$

wherein SR_{L} is the adjusted derating rate,

$${S}_{L}^{0}$$

is the derating rate before adjustment, R⁰ is the battery internal resistance before increase, R is the internal resistance increased according to the degree of degradation, and w₂ is a second weight.

In the following, effects of the examples herein will be described with parameter graphs to illustrate the effects of adjusting/different derating conditions.

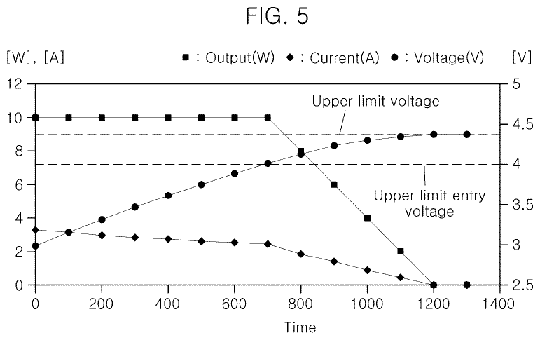

FIG. 5 illustrates an example of derating control in a battery in an initial state according to an example.

Referring to FIG. 5, while charging a battery in a BOL state with maximum output, the battery voltage reaches an upper limit entry voltage (e.g., ~Time=700), and as a result, the battery controller 111 may enter derating control. Under the derating control, the output is limited within a limited output obtained by applying a derating rate (here, 1.0), and the battery voltage may remain below the upper limit voltage.

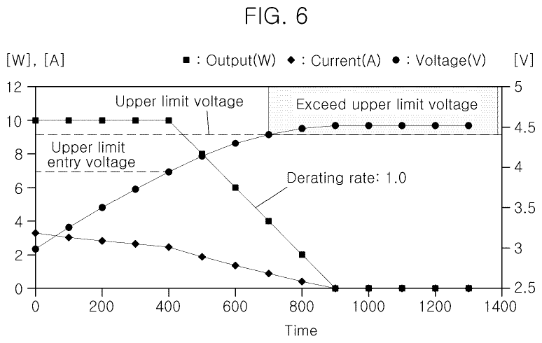

FIG. 6 illustrates an example of the result of derating control performed when derating conditions are not adjusted in a battery with increased internal resistance.

In FIG. 6, each derating condition is assumed to be the same as in the case of FIG. 5 (e.g., at BOL). In this case, if/when entering derating control at an upper limit voltage based on the BOL, due to the increase in internal resistance caused by battery degradation, the increase in battery voltage occurs more rapidly than in the BOL state. The derating rate also remains unchanged (e.g., is the derating rate of the BOL) so the battery voltage is shown to exceed the upper limit voltage, despite the derating control.

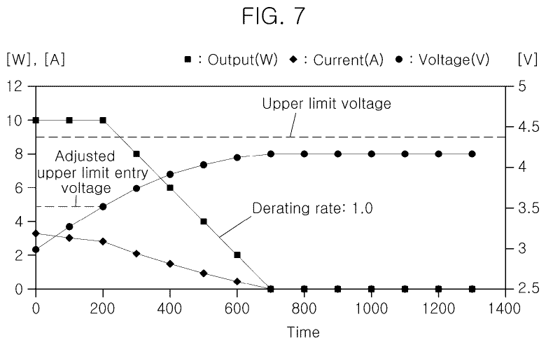

FIG. 7 illustrates an example of derating control performed if/when an entry voltage has been adjusted in a battery with increased internal resistance according to an example of the present disclosure.

As a battery degrades, an upper limit entry voltage may be adjusted lower based on the rate at which internal resistance increases. Accordingly, in FIG. 7, entry into derating control may occur earlier (e.g., than in the example of FIG. 6) and the battery voltage may remain below the upper limit voltage, unlike the case in FIG. 6.

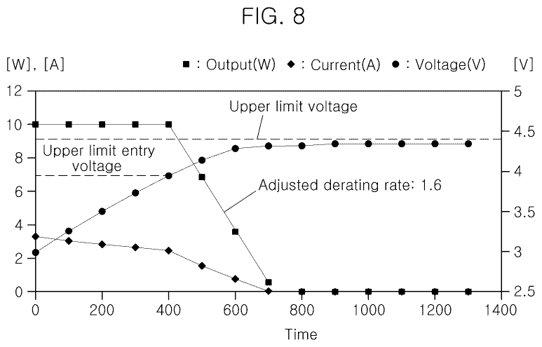

FIG. 8 illustrates an example of derating control wherein a derating rate has been adjusted in a battery with increased internal resistance according to an example of the present disclosure.

As the battery degrades, the derating rate may be adjusted higher (e.g., 1.6) based on the rate at which internal resistance increases. Accordingly, in FIG. 8, entry into derating control may occurs at the same time point/conditions as in FIG. 6, but the limited output may decrease more rapidly so that the battery voltage remains less than the upper limit voltage despite the increase in internal resistance, unlike in the case of FIG. 6.

According to the examples described herein, the battery management device 110 may manage the battery voltage by entry voltage adjustment and/or derating rate adjustment, in consideration of the degree of battery degradation. The battery management device 110 (e.g., the battery management controller 111) may transmit limited output information to other devices. Furthermore, the battery management device 110 may adjust weights of the entry voltage adjustment and/or the derating rate adjustment to provide derating optimized for the state of the device and/or intended goals for battery 112 management. This may prevent excessive voltage rise or voltage drop in a battery, thereby slowing battery degradation and thus mitigating performance degradation.

Various aspects of the present disclosure are directed to providing a device and a method for battery management, wherein an effective battery operation strategy can be provided in response to a battery's degradation.

The technical effects to be achieved in an example of the present disclosure may not be limited to the technical effects mentioned herein. Other technical effects not mentioned herein may be clearly understood by those skilled in the art to which the present disclosure pertains from the present descriptions.

As a means of solving existing technical problem (e.g., as mentioned herein and otherwise in the related art), the present disclosure provides a battery management device including: a battery; and a battery controller configured to, based on the extent of internal resistance increase according to the degree of the battery's degradation, adjust at least one of: an entry voltage for entering derating control to limit an output of the battery; or a derating rate (slew rate) at which the output is limited in case that the battery controller enters the derating control as the battery's voltage reaches the entry voltage.

For example, the battery controller may be further configured to output a current output limit value, determined based on the derating rate, in case of entering the derating control according to the entry voltage.

For example, the entry voltage may include an upper limit entry voltage, applied during charging of the battery, and a lower limit entry voltage, applied during discharging of the battery.

For example, the battery controller may be further configured to adjust the upper limit entry voltage, based on a predetermined battery upper limit voltage, the upper limit entry voltage, and the extent of internal resistance increase.

For example, the battery controller may be further configured to: determine an upper limit margin by multiplying a value, obtained by subtracting the upper limit entry voltage from the battery upper limit voltage, by the extent of internal resistance increase; and adjust the upper limit entry voltage by subtracting the determined upper limit margin from the battery upper limit voltage.

For example, the battery controller may be further configured to adjust the lower limit entry voltage, based on a predetermined battery lower limit voltage, the lower limit entry voltage, and the extent of internal resistance increase.

For example, the battery controller may be further configured to: determine a lower limit margin by multiplying a value, obtained by subtracting the battery lower limit voltage from the lower limit entry voltage, by the extent of internal resistance increase; and adjust the lower limit entry voltage by adding the determined lower limit margin to the battery lower limit voltage.

For example, the derating rate may include an upper limit voltage derating rate applied during charging of the battery and a lower limit voltage derating rate applied during discharging of the battery.

For example, the battery controller may be further configured to adjust the derating rate by a value obtained by multiplying the derating rate by the extent of internal resistance increase.

For example, the battery controller may be further configured to apply different weights to the entry voltage and the derating rate in case of adjusting both the entry voltage and the derating rate.

For example, the battery controller may be further configured to adjust the entry voltage per Equation 1 and/or the derating rate per Equation 2 during charging of the battery:

$${V}_{UE} = {V}_{UT} - ( {V}_{UT} - {V}_{UE}^{0} ) \cdot ( \frac{R}{{R}^{0}} ) \cdot {w}_{1} \qquad [ Equation 1 ]$$

$${SR}_{U} = {SR}_{U}^{0} \cdot ( \frac{R}{{R}^{0}} ) \cdot {w}_{2} \qquad [ Equation 2 ]$$

wherein V_{UE} is the adjusted entry voltage, V_{UT} is the predetermined battery upper limit voltage,

$${V}_{UE}^{0}$$

is the entry voltage before adjustment, SR_{U} is the adjusted derating rate,

$${SR}_{U}^{0}$$

is the derating rate before adjustment, R⁰ is the battery internal resistance before increase, R is the internal resistance increased according to the degree of degradation, w₁ is a first weight, and w₂ is a second weight.

For example, the battery controller may be further configured to adjust the entry voltage per Equation 3 and the derating rate per Equation 4 during discharging of the battery:

$${V}_{LE} = {V}_{LT} + ( {V}_{LE}^{0} - {V}_{LT} ) \cdot ( \frac{R}{{R}^{0}} ) \cdot {w}_{1} \qquad [ Equation 3 ]$$

$${SR}_{L} = {SR}_{L}^{0} \cdot ( \frac{R}{{R}^{0}} ) \cdot {w}_{2} \qquad [ Equation 4 ]$$

wherein V_{LE} is the adjusted entry voltage, V_{LT} is the predetermined battery lower limit voltage

$${V}_{LE}^{0}$$

is the entry voltage before adjustment, SR_{L} is the adjusted derating rate,

$${S}_{L}^{0}$$

is the derating rate before adjustment, R⁰ is the battery internal resistance before increase, R is the internal resistance increased according to the degree of degradation, w₁ is a first weight (may be the same or different than in Equation 1), and w₂ is a second weight (may be the same or different than in Equation 2).

For example, the battery controller may be further configured to: have a first state or a second state; in the first state, determine the first weight to be a value greater than the second weight; and in the second state, determine the first weight to be a value less than the second weight.

For example, the battery controller may be further configured to determine the extent of internal resistance increase, based on initial internal resistance and current internal resistance of the battery, determined based on the degree of the battery's degradation.

Furthermore, an example of the present disclosure may provide a battery management method including: adjusting, by a battery controller, based on the extent of internal resistance increase according to the degree of a battery's degradation, at least one of an entry voltage for entering derating control to limit an output of a battery, or a derating rate (slew rate) at which the output is limited in case of entering the derating control as the battery's voltage reaches the entry voltage; and outputting, by the battery controller, a current output limit value, determined based on the derating rate, in case of entering the derating control according to the entry voltage.

For example, the battery management method may further include: before the adjusting operation, determining the degree of degradation by the battery controller; and determining the extent of internal resistance increase, based on the determined degree of degradation.

According to at least an example of the present disclosure, stable voltage control is possible from the beginning of life (BOL) to the end of life (EOL) of a battery, thereby slowing the degradation of the battery and improving battery stability.

In particular, the battery management device can control the voltage more effectively by using different control methods depending on the power usage mode.

Advantageous effects obtainable from the present disclosure may not be limited to the effects mentioned herein. Other effects not mentioned herein may be clearly understood by those skilled in the art to which the present disclosure pertains from the present disclosure.

The aforementioned disclosure can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc., and implementation as carrier waves (e.g., transmission over the Internet). Examples of the program instruction include machine language code such as those generated by a compiler, as well as high-level language code which may be executed by a computer using an interpreter or the like. Therefore, the above detailed description should not be construed in a limitative sense, but should be considered in an illustrative sense in all aspects. The scope of the present disclosure should not be determined by reasonable interpretation of the appended claims, and all changes and modifications within the equivalent scope of the present disclosure fall within the scope of the present disclosure.

What is claimed is:

1. A battery management device comprising:
a battery;
one or more sensors configured to measure one or more of:
a voltage of the battery;
a temperature of the battery; and
a current of the battery; and
a battery controller configured to:
receive, from the one or more sensors, information based on one or more of the voltage, the temperature or the current;
determine, based on the information, an increase in an internal resistance associated with degradation of the battery;
adjust, based on the increase in the internal resistance, at least one of:
an entry voltage for entering derating control to limit an output of the battery, or
a derating rate, wherein the derating rate is to limit the output of the battery based on a derating control triggered after the voltage of the battery reaching the entry voltage; and
controlling, based on the adjusted at least one of the entry voltage or the derating rate, output of the battery.

2. The battery management device of claim 1, wherein the battery controller is further configured to output a current output limit value, based on the derating rate, after triggering the derating control.

3. The battery management device of claim 1, wherein the entry voltage comprises: an upper limit entry voltage for use during charging of the battery, and a lower limit entry voltage for use during discharging of the battery.

4. The battery management device of claim 3, wherein the battery controller is further configured to adjust, based on a predetermined battery upper limit voltage and the increase in the internal resistance, the upper limit entry voltage.

5. The battery management device of claim 4, wherein the battery controller is further configured to:
determine an upper limit margin by multiplying a difference between the upper limit entry voltage and a battery upper limit voltage by the increase in internal resistance increase; and
adjust the upper limit entry voltage by subtracting the determined upper limit margin from the battery upper limit voltage to determine the adjusted upper limit entry voltage.

6. The battery management device of claim 3, wherein the battery controller is further configured to adjust, based on a predetermined battery lower limit voltage and the increase in internal resistance, the lower limit entry voltage.

7. The battery management device of claim 6, wherein the battery controller is further configured to:
determine a lower limit margin by multiplying a difference between the battery lower limit voltage and the lower limit entry voltage by the increase in internal resistance; and
adjust the lower limit entry voltage by adding the determined lower limit margin to the battery lower limit voltage to determine the adjusted lower limit entry voltage.

8. The battery management device of claim 3, wherein the derating rate comprises: an upper limit voltage derating rate for use during charging of the battery, and a lower limit voltage derating rate for use during discharging of the battery.

9. The battery management device of claim 8, wherein the battery controller is further configured to adjust the derating rate based on a value obtained by multiplying the derating rate by the increase in the internal resistance.

10. The battery management device of claim 8, wherein the battery controller is further configured to adjust the entry voltage based on a first weight and adjust the derating rate based on a second weight.

11. The battery management device of claim 10, wherein the battery controller is further configured to:
adjust the upper limit entry voltage according to Equation 1:
$${V}_{UE} = {V}_{UT} - ( {V}_{UT} - {V}_{UE}^{0} ) \cdot ( \frac{R}{{R}^{0}} ) \cdot {w}_{1} , \qquad [ Equation 1 ]$$
and
adjust the upper limit voltage derating rate according to Equation 2:
$${SR}_{U} = {SR}_{U}^{0} \cdot ( \frac{R}{{R}^{0}} ) \cdot {w}_{2} , \qquad [ Equation 2 ]$$
wherein V_{UE} is the adjusted upper limit entry voltage, V_{UT} is a predetermined battery upper limit voltage,
$${V}_{UE}^{0}$$
is the upper limit entry voltage without adjustment, SR_{U} is the adjusted upper limit voltage derating rate,
$${SR}_{U}^{0}$$
is the upper limit voltage derating rate without adjustment, R⁰ is an initial internal resistance, R is an increased internal resistance increased from the initial internal resistance by the increase in the internal resistance, w₁ is the first weight, and w₂ is the second weight.

12. The battery management device of claim 10, wherein the battery controller is further configured to:
adjust the lower limit entry voltage according to Equation 3:
$${V}_{LE} = {V}_{LT} + ( {V}_{LE}^{0} - {V}_{LT} ) \cdot ( \frac{R}{{R}^{0}} ) \cdot {w}_{1} , \qquad [ Equation 3 ]$$
and
adjust the lower limit voltage derating rate according to Equation 4:
$${SR}_{L} = {SR}_{L}^{0} \cdot ( \frac{R}{{R}^{0}} ) \cdot {w}_{2} , \qquad [ Equation 4 ]$$
wherein V_{LE} is the adjusted lower limit entry voltage, V_{LT} is a predetermined battery lower limit voltage,
$${V}_{LE}^{0}$$
is the lower limit entry voltage without adjustment, SR_{L} is the adjusted lower limit voltage derating rate,
$${S}_{L}^{0}$$
is the lower limit voltage derating rate without adjustment, R⁰ is an initial internal resistance before increase, R is an increased internal resistance increased from the initial internal resistance increased by the increase in the internal resistance, w₁ is the first weight, and w₂ is the second weight.

13. The battery management device of claim 11, wherein the battery controller is further configured to set the first weight to be greater than the second weight.

14. The battery management device of claim 1, wherein the battery controller is further configured to determine the increase in the internal resistance, based on an initial internal resistance and a current internal resistance of the battery determined based on a degree of degradation of the battery.

15. The battery management device of claim 1, wherein the battery controller is configured to control output of the battery by sending, to an electronic device configured to be powered by the battery, limited output information based on the adjusted at least one of the entry voltage or the derating rate, wherein the electronic device receives, based on the limited output information, power based on the adjusted at least one of the entry voltage or the derating rate.

16. A battery management method comprising:
receiving, by a battery controller from one or more sensors of a battery, information based on one or more of: a voltage of the battery, a temperature of the battery or a current of the battery;
determining, based on the information, an increase in an internal resistance associated with degradation of the battery;
adjusting, based on the increase in the internal resistance, at least one of:
an entry voltage for entering derating control to limit an output of a battery, or
a derating rate, wherein the derating rate is to limit the output of the battery based on a derating control triggered after a voltage reaching the entry voltage; and
outputting, by the battery controller, a current output limit value, based on the derating rate, for use based on a voltage of the battery satisfying the entry voltage; and
controlling, based on the current output limit value and the adjusted at least one of the entry voltage or the derating rate, power output by the battery.

17. The battery management method of claim 16, wherein the determining the increase in the internal resistance is based on a degree of the degradation of the battery.

18. A battery management system comprising:
a battery;
one or more sensors associated with the battery;
one or more devices configured to receive power from the battery; and
a battery controller configured to:
receive, from the one or more sensors associated with the battery, information indicating a state of health of the battery;
determine, based on the information, an increase in an internal resistance of the battery;
adjust, based on the increase in the internal resistance, at least one of:
an entry voltage for triggering derating control of the battery, or
a derating, wherein the derating rate is to limit an output of the battery based on a voltage of the battery reaching the entry voltage; and
causing the battery to output, to the one or more devices, power based on the adjusted at least one of the entry voltage or the derating rate.

19. The battery management system of claim 18, wherein the information indicating the state of health of the battery comprises one or more of a voltage, a temperature, or a current, and
wherein the battery controller is configured to determine the state of health of the battery based on the information.

20. The battery management system of claim 18, wherein the causing the battery to output the power comprises causing the battery to output the power at an adjusted derating rate, wherein the adjusted derating rate is based on an original derating rate scaled by the increase in the internal resistance.
